(19) United States
(12) Patent Application Publication
(10) Pub. No.: US 2008/0117598 A1
(43) Pub. Date: May 22, 2008

(54) THERMAL MANAGEMENT MODULE AND ELECTRONIC ASSEMBLY USING THE SAME

(75) Inventors: I-Feng Hsu, Taipei City (TW); Chieh-Wei Chang, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: COMPAL ELECTRONICS, INC., Taipei City (TW)

(21) Appl. No.: 11/836,789

(22) Filed: Aug. 10, 2007

(30) Foreign Application Priority Data
Nov. 17, 2006 (TW) 95142532

(51) Int. Cl. H05K 7/20

(52) U.S. Cl. 361/704; 361/710

(57) ABSTRACT

A thermal management module includes a heat absorber, a fixing element, an elastic element and a confining structure is provided. The heat absorber has a through hole. The through hole has a first end, a second end, and a shoulder. The shoulder is located between the first end and the second end. The fixing element has a head part and a shaft part. The head part is located inside the through hole and between the first end and the shoulder. The shaft part is in the through hole. The elastic element is located inside the through hole, and surrounds the fixing element. The confining structure is connected to the heat absorber and extends to the through hole to confine the head part of the fixing element inside the through hole.

### CROSS-REFERENCE TO RELATED APPLICATION

This application claims the priority benefit of Taiwan application serial no. 95142532, filed Nov. 17, 2006. All disclosure of the Taiwan application is incorporated herein by reference.

### BACKGROUND OF THE INVENTION

1. Field of the Invention

The present invention relates to a thermal management module. More particularly, the present invention relates to a high reliable thermal management module and an electronic assembly using the same.

2. Description of Related Art

In recent years, the general trend of portable electronic apparatus is multi-functional, and thus IC chips are required to be more powerful in function and operated in higher frequency. As the operating frequency of IC chips is increased, more heat is generated correspondingly, and thus a thermal management module becomes an indispensable device for a portable electronic apparatus with a small size.

FIG. 1 is a top view of a circuit board having a heat source, carrying a conventional thermal management module. FIG. 2 is a cross-sectional view taken along line A-A of FIG. 1. Referring to FIGS. 1 and 2, the circuit board 50 includes a heat source 52, the conventional thermal management module 100 is assembled to the circuit board 50 and covers the heat source 52.

The thermal management module 100 includes a heat absorber 110, fixing elements 120, elastic elements 130 and E-shape rings 140. The heat absorber 110 has through holes 112 located on its four corners, wherein each through hole 112 has a first end 112a and a second end 112b. The fixing elements 120 are located in the through holes 112 respectively. The elastic elements 130 are also located in the through holes 112 respectively, and surround the fixing elements 120 respectively. Each fixing element 120 has an annular groove 120a, and the E-shape rings 140 are locked with the annular grooves 120a respectively, wherein the diameter of the E-shape rings 140 is greater than that of the second end 112b.

Each fixing element 120 has an external thread, and each post 54 of the circuit board 50 has an internal thread correspondingly. Therefore, the fixing elements 120 can be fastened to the posts 54 respectively by the threads, and the heat absorber 110 may contacts the heat source 52 closely under a predefined pressure due to the elasticity of the elastic elements 130. Moreover, the E-shape rings 140 may prevent the fixing elements 120 from escaping from the through holes 112 due to the elasticity of the elastic elements 130 before the heat absorber 110 being fastened to the posts 54.

Though the E-shape rings 140 may prevent the fixing elements 120 from escaping from the through holes 112, however, if the E-shape rings 140 is loosened, and drops on the circuit board 50, the circuit board 50 will be damaged due to a short-circuit. Therefore, a new fixing method substituting the conventional fixing method of a thermal management module should be provided to avoid the aforementioned problem. Moreover, each of the conventional fixing elements 120 must have an annular groove 120a for accommodating the corresponding E-shape ring 140. Therefore, the fixing elements 120 have to be specially made, and the cost will be increased accordingly.

### SUMMARY OF THE INVENTION

The present invention is direct to a thermal management module having a relatively high reliability.

The present invention is direct to an electronic assembly using the thermal management module, having a relatively high reliability.

The present invention provides a thermal management module comprising a heat absorber, a fixing element, an elastic element and a confining structure. The heat absorber has a through hole having a first end, a second end and a shoulder. The shoulder is located between the first end and the second end. The fixing element has a head part and a shaft part connected to the head part. The head part is located inside the through hole and between the first end and the shoulder. The shaft part is located in the through hole. The elastic element is located inside the through hole, and surrounds the fixing element. The confining structure is integrally formed with the heat absorber and extends to the through hole to confine the head part of the fixing element inside the through hole.

In an embodiment of the present invention, the diameter of the first end is greater than that of the second end.

In an embodiment of the present invention, the elastic element surrounds the shaft part of the fixing element.

In an embodiment of the present invention, the confining structure is bumps arranged along the edge of the first end of the through hole and protruding from the first end of the through hole towards the center of the through hole.

In an embodiment of the present invention, a portion of the shaft part passes through the second end and extends to the outside of the heat absorber.

In an embodiment of the present invention, the elastic element stores an elasticity under a pressure of the head part and the shoulder.

In an embodiment of the present invention, the elastic element may be a spring.

In an embodiment of the present invention, the fixing element is a bolt comprising the head part and the shaft part.

The present invention further provides an electronic assembly including a circuit board and a thermal management module. The circuit board has a heat source thereon. The thermal management module includes a heat absorber, a fixing element, an elastic element and a confining structure. The heat absorber contacts the heat source and has a through hole. The through hole has a first end, a second end and a shoulder located between the first end and the second end. The fixing element has a head part and a shaft part connected to the head part, wherein the head part is located in the through hole and between the first end and the shoulder. The shaft part is located in the through hole and is assembled to the circuit board. The elastic element is located inside the through hole, and surrounds the fixing element. The confining structure is integrally formed with the heat absorber and extends to the through hole to confine the head part of the fixing element inside the through hole.

In an embodiment of the present invention, the diameter of the first end is greater than that of the second end.

In an embodiment of the present invention, the elastic element surround the shaft part of the fixing element.

In an embodiment of the present invention, the confining structure is bumps arranged along the edge of the first end of the through hole and protruding from the first end of the through hole towards the center of the through hole.

In an embodiment of the present invention, a portion of the shaft part passes through the second end and extends to the outside of the heat absorber.

In an embodiment of the present invention, the elastic element stores an elasticity under a pressure of the head part and the shoulder.

In an embodiment of the present invention, the elastic element may be a spring.

In an embodiment of the present invention, the fixing element is a blot comprising the head part and the shaft part.

In an embodiment of the present invention, the circuit board further comprises a post having an internal thread coupled to an external thread of the shaft part of the fixing element.

The confining structure of the present invention can be integrally formed with a heat absorber, therefore the confining structure is not likely to be loosened, and the reliability of the electronic assembly is improved.

In order to make the aforementioned and other features and advantages of the present invention comprehensible, an embodiment accompanied with figures is described in detail below.

### BRIEF DESCRIPTION OF THE DRAWINGS

FIG. 1 is a top view of a circuit board having a heat source, carrying a conventional thermal management module.

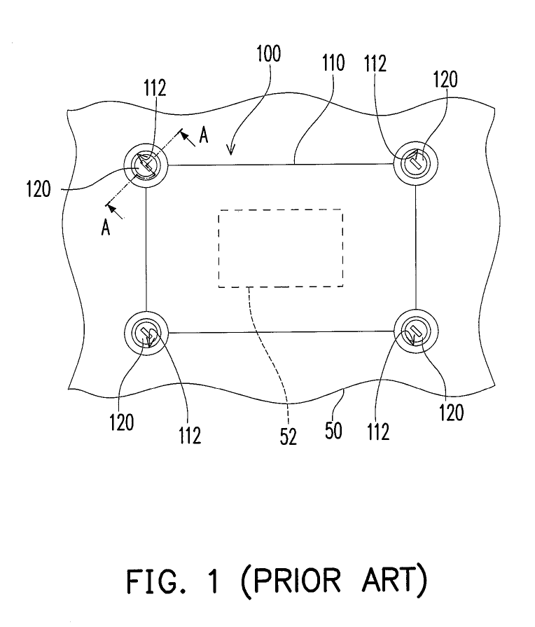

FIG. 2 is a cross-sectional view taken along line A-A of FIG. 1.

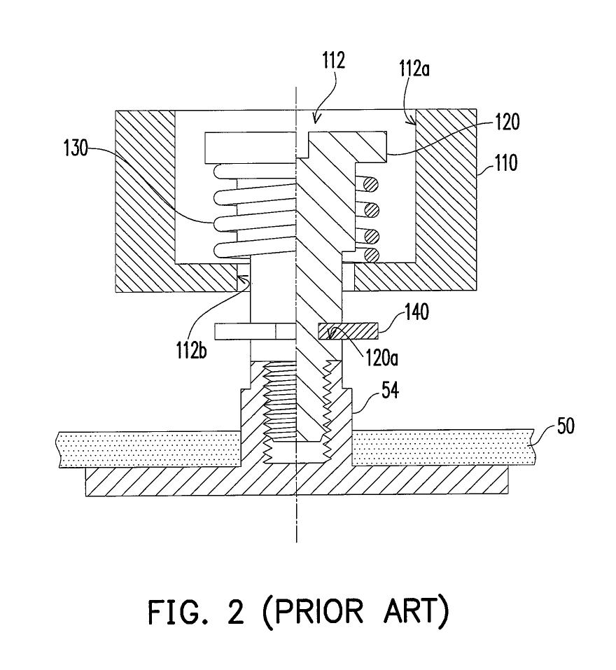

FIG. 3 is a top view of a thermal management module according to an embodiment of the present invention.

FIG. 4 is a cross-sectional view taken along line B-B of FIG. 3.

FIG. 5 is an exploded view of the thermal management module of FIG. 3.

FIG. 6 is a top view of an electronic assembly according to another embodiment of the present invention.

FIG. 7 is a cross-sectional view taken along line C-C of FIG. 6.

### DESCRIPTION OF EMBODIMENTS

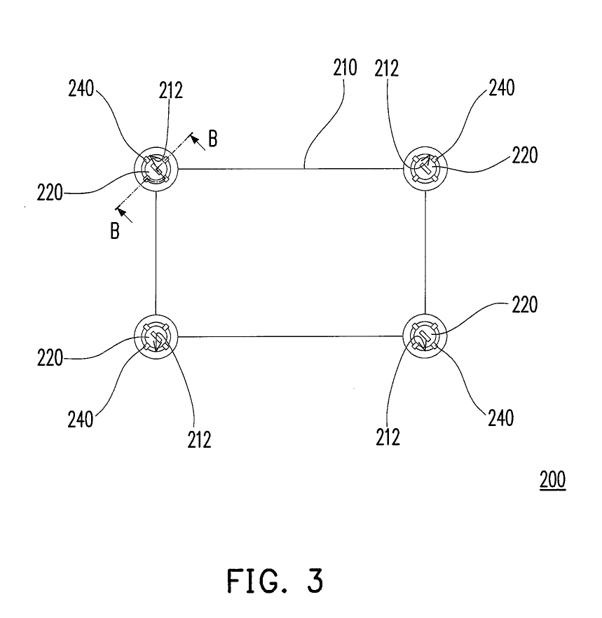

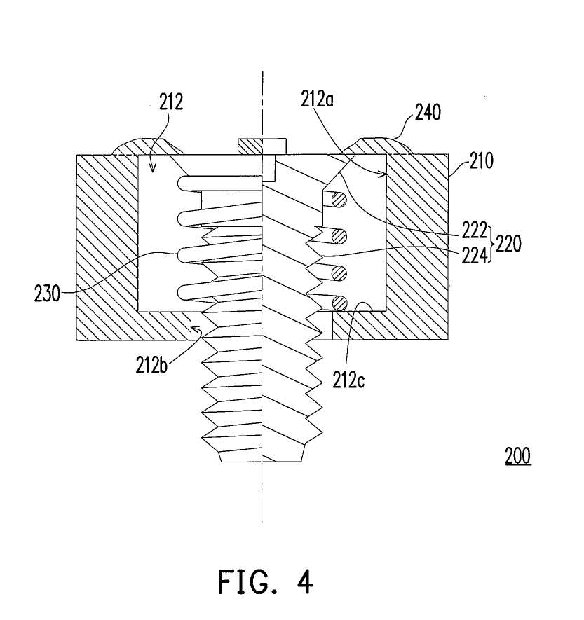

FIG. 3 is a top view of a thermal management module according to an embodiment of the present invention. FIG. 4 is a cross-sectional view taken along line B-B of FIG. 3. Referring to FIGS. 3 and 4, the thermal management module 200 includes a heat absorber 210, fixing elements 220, elastic elements 230 and confining structures 240. The heat absorber 210 has through holes 212. Each of the through hole 212 has a first end 212a, a second end 212b and a shoulder 212c, wherein the shoulder 212c is located between the first end 212a and the second end 212b.

Each of the fixing element 220 includes a head part 222 and a shaft part 224 connected to the head part 222, wherein the head part 222 is located in the corresponding through hole 212 and is located between the first end 212a and the second end 212b, and the shaft part 224 is also located in the through hole 212. The elastic element 230 is also located in the through hole 212 and surrounds the fixing element 220. The confining structure 240 is connected to the heat absorber 210 and extends to the through hole 212 to confine the head part 222 of the fixing element 220 inside the through hole 212, and prevent the fixing element 220 and elastic element 230 from escaping from the heat absorber 210.

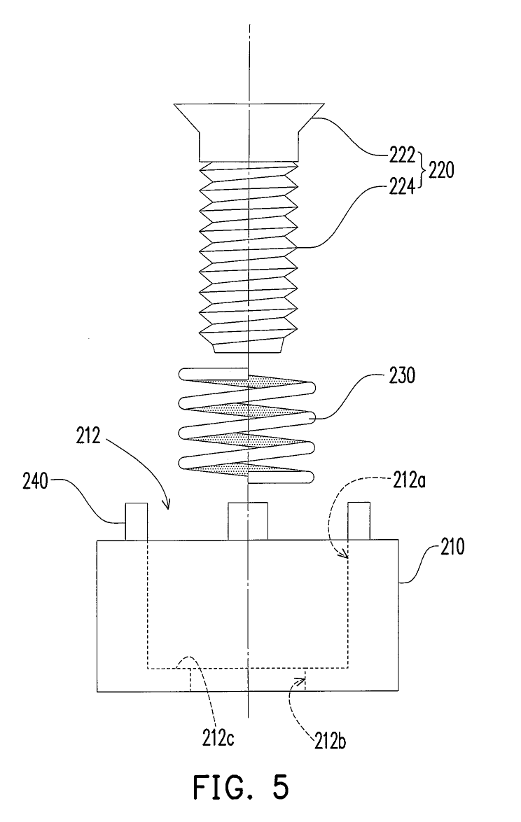

FIG. 5 is an exploded view of the thermal management module of FIG. 3. Referring to FIGS. 3, 4 and 5, in the present embodiment, the fixing element 220 and the elastic element 230 can be allocated into the through hole 212 through the first end 212a, and the elastic element 230 may surround the shaft part 224 of the fixing element 220. The diameter of the second end 212b is less than that of the first end 212a, and the shoulder 212c may prevent the elastic element 230 from escaping from the heat absorber 210 through the second end 212b, so as to confine the fixing element 220 and the elastic element 230 in the through hole 212.

In addition, the diameter of the second end 212b allows the shaft part 224 of the fixing element 220 passing through, such that a portion of the shaft part 224 may extend to the outside of the heat absorber 210. Moreover, the elastic element 230 stores an elasticity under a pressure of the head part 222 and the shoulder 212c.

In the present embodiment, the confining structure 240 may be bumps arranged along the edge of the first end 212a. For example, each through hole 212 has four confining structure 240 (shown as FIG. 3). To allocate the fixing element 220 and the elastic element 230 into the through hole 212 through the first end 212a, the confining structures 240 should not extend to the through hole 212 before the fixing element 220 and the elastic element 230 are allocated into the through hole 212, shown as FIG. 5. Then, after the fixing element 220 and the elastic element 230 are allocated into the through hole 212 respectively, the confining structures 240 can be deformed by die-casting and extends to the through hole 212, shown as FIG. 4.

As described above, referring to FIG. 4, after the fixing element 220 and the elastic element 230 are allocated into the through hole 212, the confining structure 240 is protruded towards the center of the through hole 212 from the first end 212a to prevent the fixing element 220 and the elastic element 230 from escaping from the heat absorber 210.

The elastic element 230 may be a spring, and the fixing element 220 may be a blot comprising the head part 222 and the shaft part 224.

In the present embodiment, the confining structure 240 is integrally formed with the heat absorber 210, and therefore the confining structure 240 is not likely to be loosened.

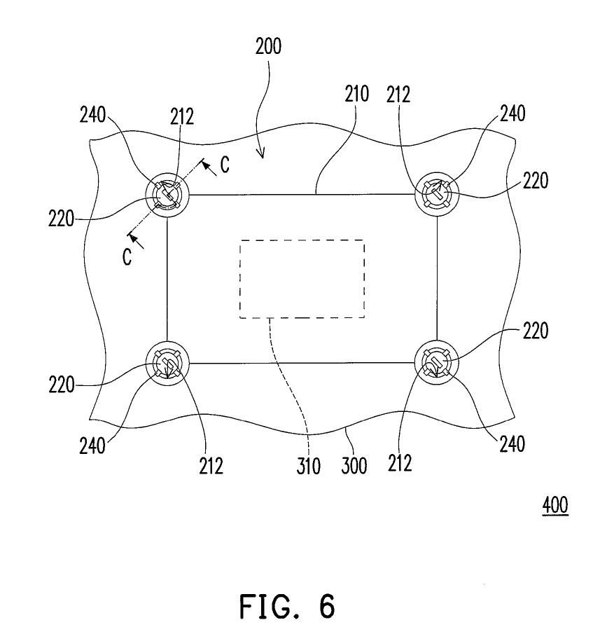

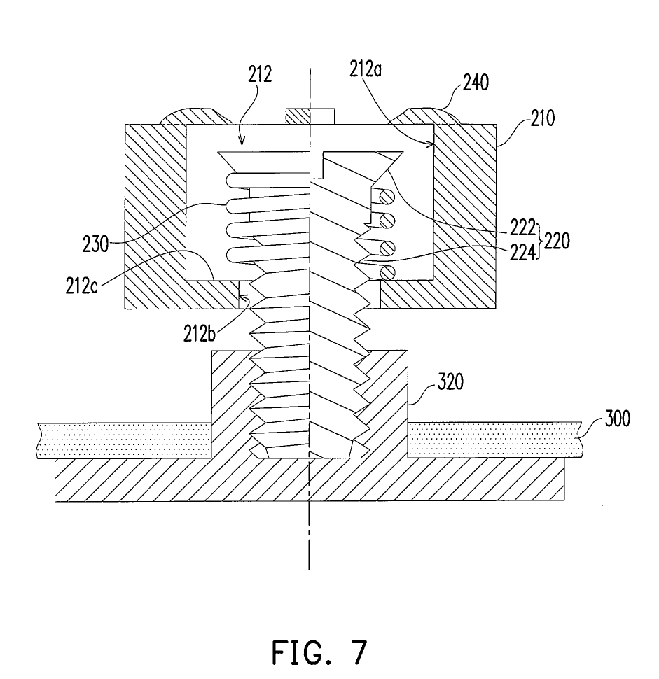

FIG. 6 is a top view of an electronic assembly according to another embodiment of the present invention. FIG. 7 is a cross-sectional view taken along line C-C of FIG. 6. Referring to FIGS. 6 and 7, the electronic assembly 400 includes a circuit board 300 and a thermal management module 200. The operation of the thermal management module 200 has been described in detail in the embodiment in FIGS. 3-5, and thus the repeated description will be omitted hereby. The circuit board 300 has a heat source 310. The heat absorber 210 contacts the heat source 310 for removing the heat of the heat source 310. The shaft part 224 of the fixing element 220 is assembled to the circuit 300.

In the present embodiment, the circuit board 300 has a post 320 having an internal thread. The shaft part 224 of the fixing element 220 has an external thread corresponding to the internal thread of the post 320. The thermal management module 200 can be assembled to the circuit board 300 by fastening the fixing element 220 to the post 320 by the threads. Moreover, after the thermal management module 200 is assembled to the circuit board 300, the heat source 310 contacts the heat absorber 210, and the elastic element 230 stores an elasticity under the pressure of the head part 222 and the shoulder 212c. Therefore, the heat absorber 210 may contacts the heat source 310 closely under a predefined pressure, so as to improve the thermal management effect.

In the present embodiment, the situation of the confining structure 240 being loosened and dropping onto the circuit board 300 can be avoided. Therefore, the reliability of the electronic assembly 400 can be improved.

In summary, a confining structure of the present invention is integrally formed with a heat absorber. Thus, the confining structure is not likely to be loosened, and the reliability of the electronic assembly can be improved. Moreover, a fixing element in the present invention can be a common used fixing element, no need of a special fixing element having an annular groove as that of a conventional fixing element, therefore the cost can be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thermal management module, comprising:
a heat absorber, having a through hole, wherein the through hole has a first end, a second end and a shoulder located between the first end and the second end;
a fixing element, having a head part and a shaft part connected to the head part, wherein the head part is located in the through hole and between the first end and the shoulder, and the shaft part is located in the through hole;
an elastic element, located in the through hole and surrounding the fixing element; and
a confining structure, integrally formed with the heat absorber, extending to the through hole, and configured to confine the head part of the fixing element in the through hole.

2. The thermal management module as claimed in claim 1, wherein the diameter of the first end is greater than that of the second end.

3. The thermal management module as claimed in claim 1, wherein the elastic element surrounds the shaft part of the fixing element.

4. The thermal management module as claimed in claim 1, wherein the confining structure is a plurality of fixing bumps arranged along the edge of the first end of the through hole and protruding from the first end of the through hole towards the center of the through hole.

5. The thermal management module as claimed in claim 1, wherein a portion of the shaft part passes through the second end and extends to the outside of the heat absorber.

6. The thermal management module as claimed in claim 1, wherein the elastic element stores an elasticity under a pressure of the head part and the shoulder.

7. The thermal management module as claimed in claim 1, wherein the elastic element is a spring.

8. The thermal management module as claimed in claim 1, wherein the fixing element is a bolt having the head part and the shaft part.

9. An electronic assembly, comprising:
a circuit board, having a heat source thereon; and
a thermal management module, comprising:
a heat absorber, contacting the heat source, and having a through hole, wherein the through hole has a first end, a second end and a shoulder located between the first end and the second end;
a fixing element, having a head part and a shaft part connected to the head part, wherein the head part is located in the through hole and between the first end and the shoulder, and the shaft part is located in the through hole and assembled to the circuit board;
an elastic element, located in the through hole, surrounding the fixing element; and
a confining structure, integrally formed with the heat absorber, extending to the through hole, configured to confine the head part of the fixing element in the through hole.

10. The electronic assembly as claimed in claim 9, wherein the diameter of the first end is greater than that of the second end.

11. The electronic assembly as claimed in claim 9, wherein the elastic element surrounds the shaft part of the fixing element.

12. The electronic assembly as claimed in claim 9, wherein the confining structure is a plurality of fixing bumps arranged along the edge of the first end of the through hole and protruding from the first end of the through hole towards the center of the through hole.

13. The electronic assembly as claimed in claim 9, wherein a portion of the shaft part passes through the second end and extends to the outside of the heat absorber.

14. The electronic assembly as claimed in claim 9, wherein the elastic element stores an elasticity under a pressure of the head part and the shoulder.

15. The electronic assembly as claimed in claim 9, wherein the elastic element is a spring.

16. The electronic assembly as claimed in claim 9, wherein the fixing element is a bolt having the head part and the shaft part.

17. The electronic assembly as claimed in claim 9, wherein the circuit board further comprises a post having an internal thread coupled to an external thread of the shaft part of the fixing element.
